(19) United States
(12) Patent Application Publication
(10) Pub. No.: US 2007/0290325 A1
(43) Pub. Date: Dec. 20, 2007

(54) Surface mounting structure and packaging method thereof

(75) Inventors: Kuo-Liang Wu, Hsin-Tien City (TW); Kuo-Shu Iu, Hsin-Tien City (TW); Chih-Wei Chang, Hsin-Tien City (TW)

Correspondence Address: ROSENBERG, KLEIN & LEE, 3458 ELLICOTT CENTER DRIVE-SUITE 101, ELLICOTT CITY, MD, 21043, US

(73) Assignee: LITE-ON SEMICONDUCTOR CORPORATION

(21) Appl. No.: 11/453,803

(22) Filed: Jun. 16, 2006

(51) Int. Cl. H01L 23/48; H01L 21/44

(52) U.S. Cl. 257/696; 257/735; 438/611; 257/E23.047

(57) ABSTRACT

A surface mounting structure and a packaging method thereof comprises a chip, a first conducting wire and a second conducting wire. The two conducting wires instead of lead frame architecture of the prior art is that the lead frame and a bridge jumper connected with N junction and P junction instead of the two conducting wires. The two conducting wires are drawn out from a bottom of a package, and are pressed and bent to original surface of the surface mounting pins so as to increase space utilization rate. Thereby it is to improve a complicated lead frame architecture of the prior art, increase use space and simplify system design.

### BACKGROUND OF THE INVENTION

1. Field of the invention

The present invention relates to a surface mounting device, and more particularly to a surface mounting structure of two conducting wires and a packaging method thereof.

2. Description of the Prior Art

Recently with the rapidly development of manufacturing skills of the integrated circuit, the tinny dimensions of the electronic elements have become a necessary trend, and larger scale and higher integration of the electronic circuit so as to produce more complete productions. In this condition, the traditional assembly way of pin through hole (PTH) needs larger space of the printed circuit board to insert elements, and one side of the printed circuit board is used to insert pins of the elements and the other side is used to weld pins of the elements. Hence, a packaging method of surface mounting device (SMD) is used to assemble the electronic components on the printed circuit board at present.

Furthermore, the traditional SMD package is that lead frames are used and pins are drawn out from two sides of the package to cause larger occupation volume so as not to easily simplify the system design and it is disadvantageous to develop the tinny electronic products because of the complicated lead frame architecture.

The inventor of the present invention recognizes the above shortage should be corrected and special effort has been paid to research this field. The present invention is presented with reasonable design and good effect to resolve the above problems.

### SUMMARY OF THE INVENTION

It is a primary object of the present invention to provide a surface mounting structure and a packaging method thereof in which two conducting wires instead of lead frame architecture of the prior art is that the lead frame and a bridge jumper connected with N junction and P junction instead of the conducting wires. The conducting wires are drawn out from a bottom of a package, and are pressed and bent to original surface of the surface mounting pins so as to increase space utilization rate. Thereby it is to improve a complicated lead frame architecture of the prior art, increase use space and simplify system design.

It is another object of the present invention to provide the surface mounting structure and the packaging method thereof to increase production yield rate and reduce production equipment and production costs due to a simple design.

It is another object of the present invention to provide the surface mounting structure and the packaging method thereof to reduce material dimensions to increase contacting area to the chip so as to improve an electric quality because the conducting wires are drawn out from a bottom of the device.

For achieving the objectives stated above, the surface mounting structure of the present invention comprises a chip; a first conducting wire has a supporting portion for supporting the chip; and a second conducting wire is connected with one end of the chip.

Furthermore, for achieving the objects stated above, the packaging method of the surface mounting structure comprises connecting a first conducting wire and a second conducting wire with two ends of a chip along an axial direction of the chip; covering packaging material around the chip and the two conducting wires; drawing the two conducting wires out from a bottom of the device; and stretching and pressing the two conducting wires drawn to flat by means of a mold, and next bending the two conducting wires.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The above and further advantages of this invention may be better understood by referring to the following description, taken in conjunction with the accompanying drawings, in which:

FIG. 1 is a first schematic view of a surface mounting structure and a packaging method thereof of the present invention;

FIG. 2 is a second schematic view of the surface mounting structure and the packaging method thereof of the present invention;

FIG. 3 is a third schematic view of the surface mounting structure and the packaging method thereof of the present invention; and

FIG. 4 is a flowchart of the surface mounting structure and the packaging method thereof of the present invention.

The drawings will be described further in connection with the following detailed description of the present invention.

### DETAILED DESCRIPTION OF THE PREFERRED EMBODIMENTS

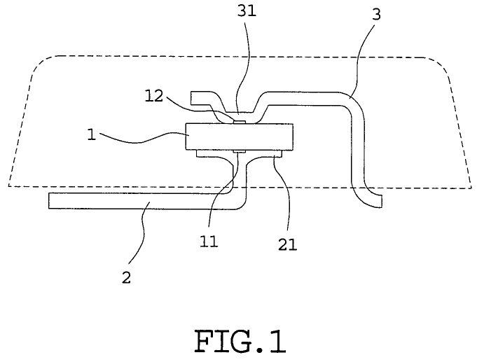

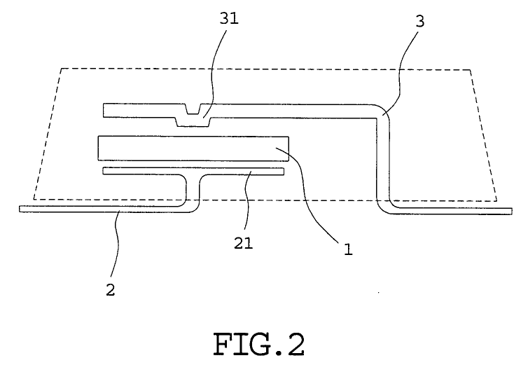

References are made from FIG. 1 to FIG. 3 which are three schematic views of a surface mounting structure and a packaging method thereof of the present invention. The surface mounting structure comprises a chip 1, a first conducting wire 2 and a second conducting wire 3. The chip 1 has a first electrode 11 and a second electrode 12. A front end of the first conducting wire 2 has a supporting portion 21 for supporting the chip 1. The second conducting wire 3 is connected with one end of the chip 1, and the first electrode 11 is electrically connected with the first conducting wire 2 and the second electrode 12 is electrically connected with the second conducting wire 3.

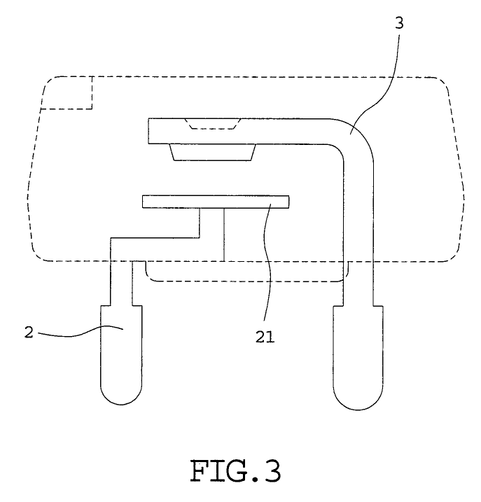

The supporting portion 21 of the first conducting wire 2 is a flat shape (similar to a platform) by means of a stretching and pressing process, the flat-shaped supporting portion 21 is horizontal to an upper flat surface and a lower flat surface of a housing for supporting the chip 1. A rear end of the first conducting wire 2 is bent and mounted on a printed circuit board, and the first conducting wire 2 is disposed on a bottom of the chip 1. A front end of the second conducting wire 3 is partially processed to form a concave portion 31 for increasing a contacting area to the chip 1 so as to increase electric quality. A rear end of the second conducting wire 3 is bent and installed on the printed circuit board, and the second conducting wire 3 is disposed on a top of the chip 1. Furthermore, the first conducting wire 2 and the second conducting wire 3 are not only bent and installed on the printed circuit board but also inserted on the printed circuit board (shown in FIG. 3).

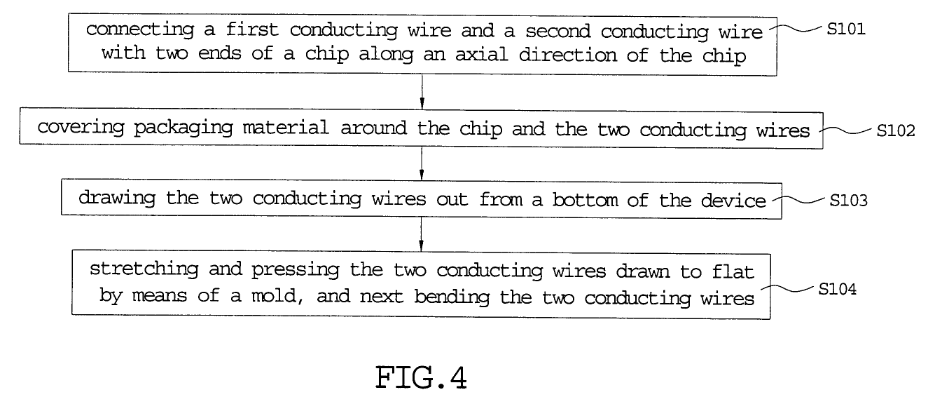

Reference is made to FIG. 4 which is a flowchart of the surface mounting structure and the packaging method thereof of the present invention. The packaging method comprises the steps of: connecting a first conducting wire and a second conducting wire with two ends of a chip along an axial direction of the chip (S101); covering packaging material around the chip and the two conducting wires (S102); drawing the two conducting wires out from a bottom of the device (S103); and stretching and pressing the two conducting wires drawn to flat by means of a mold, and next bending the two conducting wires (S104).

The surface mounting structure and a packaging method thereof in which the two conducting wires instead of lead frame architecture of the prior art is that the lead frame and a bridge jumper connected with N junction and P junction instead of the two conducting wires. The two conducting wires are drawn out from a bottom of a package, and are pressed and bent to original surface of the surface mounting pins so as to increase space utilization rate. Thereby it is to improve a complicated lead frame architecture of the prior art, increase use space and simplify system design. Furthermore, it is to increase production yield rate and reduce production equipment and production costs.

It follows from what has been said that the surface mounting structure and a packaging method thereof has the following advantages:

1. Improving the complicated lead frame architecture of the prior art;

2. Increasing the use space and simplifying the system design;

3. Reducing the material dimensions;

4. Improving the electric quality;

5. Increasing the production yield rate and reducing the production equipment; and

6. Reducing the production costs.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A surface mounting structure, comprising:
a chip;
a first conducting wire having a supporting portion for supporting the chip; and a second conducting wire connected with one end of the chip.

2. The surface mounting structure as claimed in claim 1, wherein the chip has a first electrode and a second electrode, and the first electrode is electrically connected with the first conducting wire and the second electrode is electrically connected with the second conducting wire.

3. The surface mounting structure as claimed in claim 1, wherein the supporting portion of the first conducting wire is a flat shape by means of a stretching and pressing process.

4. The surface mounting structure as claimed in claim 1, wherein the first conducting wire is disposed on a bottom of the chip.

5. The surface mounting structure as claimed in claim 1, wherein the second conducting wire is partially processed to form a concave portion for increasing a contacting area to the chip.

6. The surface mounting structure as claimed in claim 1, wherein the second conducting wire is disposed on a top of the chip.

7. A packaging method of the surface mounting structure, comprising the steps of:
connecting a first conducting wire and a second conducting wire with two ends of a chip along an axial direction of the chip;
covering packaging material around the chip and the two conducting wires;
drawing the two conducting wires out from a bottom of the device; and
stretching and pressing the two conducting wires drawn to flat by means of a mold, and next bending the two conducting wires.

8. The packaging method of the surface mounting structure as claimed in claim 7, wherein the chip has a first electrode and a second electrode, and the first electrode is electrically connected with the first conducting wire and the second electrode is electrically connected with the second conducting wire.

9. The packaging method of the surface mounting structure as claimed in claim 7, wherein the first conducting wire has a supporting portion that is a flat shape by means of a stretching and pressing process.

10. The packaging method of the surface mounting structure as claimed in claim 7, wherein the first conducting wire is disposed on a bottom of the chip.

11. The packaging method of the surface mounting structure as claimed in claim 7, wherein the second conducting wire is partially processed to form a concave portion for increasing a contacting area to the chip.

12. The packaging method of the surface mounting structure as claimed in claim 7, wherein the second conducting wire is disposed on a top of the chip.
